(19) United States
(12) Patent Application Publication
(10) Pub. No.: US 2025/0035673 A1
(43) Pub. Date: Jan. 30, 2025

(54) MEASURING DEVICE

(71) Applicant: Nuvoton Technology Corporation Japan, Kyoto (JP)

(72) Inventors: Kouichi MIKAMI, Osaka (JP); Takuya ISHII, Osaka (JP)

(21) Appl. No.: 18/892,599

(22) Filed: Sep. 23, 2024

Related U.S. Application Data
(63) Continuation of application No. PCT/JP2023/009117, filed on Mar. 9, 2023.

(30) Foreign Application Priority Data
Mar. 28, 2022 (JP) 2022-051660

(51) Int. Cl. G01R 15/04; G01R 19/25; G01R 31/3842; G01R 31/389

(52) U.S. Cl. CPC G01R 15/04; G01R 19/25; G01R 31/3842; G01R 31/389

(57) ABSTRACT

A measuring device includes a voltage divider resistor component, an AD converter component, and a calculator. The voltage divider resistor component includes a plurality of voltage divider resistors that divide a voltage of a battery (object to be measured). The AD converter component includes a plurality of AD converters that convert voltages of at least two of the plurality of voltage divider resistors of the voltage divider resistor component into a plurality of first digital data items, the voltages each being a voltage across a voltage divider resistor among the at least two of the plurality of voltage divider resistors. The calculator calculates the voltage (electrical parameter) of the battery (object to be measured) from the plurality of first digital data items converted by the plurality of AD converters.

### CROSS REFERENCE TO RELATED APPLICATIONS

This is a continuation application of PCT International Application No. PCT/JP2023/009117 filed on Mar. 9, 2023, designating the United States of America, which is based on and claims priority of Japanese Patent Application No. 2022-051660 filed on Mar. 28, 2022. The entire disclosures of the above-identified applications, including the specifications, drawings and claims are incorporated herein by reference in their entirety.

### FIELD

The present disclosure relates to a measuring device that measures an electrical parameter of an object to be measured.

### BACKGROUND

A degradation state of a battery can be determined by measuring the internal impedance. For example, Patent Literature (PTL) 1 proposes a method of calculating an alternating-current (AC) impedance as the internal impedance with high accuracy by applying an alternating current to the battery using a transformer and measuring the current and the voltage across the battery.

In order to calculate an AC impedance, an analog-to-digital converter (hereafter abbreviated as “AD converter”) that converts a measured value of a current or a voltage into digital data is used. When an object to be measured is a battery which is a cell stack including multistage cells and having a high voltage of, for example, tens of volts or more, the battery voltage is divided by voltage divider resistors such that an input voltage to the AD converter falls within the allowable input voltage (usually a few or several volts). For example, voltage Vx obtained by dividing battery voltage Vb of a cell stack by a voltage divider resistor having resistance value R1 and a voltage divider resistor having resistance value R2 is expressed by the following equation.

$$Vx = Vb \times R 1 / ( R 1 + R 2 )$$

Here, if resistance value R2 is sufficiently larger than resistance value R1 and the accuracy of the resistance values is ±a %, the variation in voltage divider ratio R1/(R1+R2) is approximately ±2a %. For example, if the representative value of the above voltage Vx is 5 V and a=0.1%, the variation in voltage Vx is f 0.01 V. Accordingly, when the voltage of the object to be measured is measured using voltage divider resistors, the accuracy of the resistance values of the voltage divider resistors may have relatively large effects on the measurement accuracy of the voltage of the object to be measured.

For example, PTL 2 discloses a method of improving the accuracy of such measurement of the voltage of the object to be measured by voltage divider resistors. In PTL 2, a selector switch is controlled to sequentially connect the respective terminals of the voltage divider resistors to the capacitor, and each time the connection between each voltage divider resistor and the capacitor is switched, a conversion switch is turned on and the voltage across the capacitor is supplied to the AD converter. As a result, in PTL 2, the sum of all the digital data items obtained by inputting all voltages across the voltage divider resistors to the AD converter by the switch circuit (the selector switch and the conversion switch) and converting all the voltages across the voltage divider resistors. Therefore, in PTL 2, the accuracy of the resistance values of the voltage divider resistors is less likely to affect the measurement accuracy of the voltage of an object to be measured.

### CITATION LIST

### Patent Literature

PTL 1: Japanese Unexamined Patent Application Publication No. 2006-266814
PTL 2: Japanese Unexamined Patent Application Publication No. 2005-207826

### SUMMARY

### Technical Problem

The method disclosed in the aforementioned PTL 2 requires a switch circuit for sequentially connecting the respective terminals of the voltage divider resistors to the AD converter. Therefore, the method disclosed in PLT 2 has a problem that the measurement accuracy of the voltage (electrical parameter) of the object to be measured degrades due to switching noise generated by the switch circuit. In addition, in the method disclosed in PTL 2, the operating time of the switch circuit becomes time difference between the respective measurements of the voltages across the voltage divider resistors. Here, when measuring the AC impedance (electrical parameter) of the object to be measured, it is necessary to simultaneously measure the current and the voltage of the object to be measured. For this reason, the method disclosed in PTL 2 has a problem that simultaneousness is impaired due to such time difference and the measurement accuracy of the AC impedance of the object to be measured degrades.

In view of the above, the present disclosure aims to provide a measuring device that can improve the measurement accuracy of an electrical parameter of an object to be measured.

### Solution to Problem

In view of the above, a measuring device according to one aspect of the present disclosure includes: a voltage divider resistor component, an analog-to-digital (AD) converter component, and a calculator. The voltage divider resistor component includes a plurality of voltage divider resistors that divide a voltage of an object to be measured. The AD converter component includes a plurality of AD converters that convert voltages of at least two of the plurality of voltage divider resistors of the voltage divider resistor component into a plurality of first digital data items, the voltages each being a voltage across a voltage divider resistor among the at least two of the plurality of voltage divider resistors. The calculator calculates an electrical parameter of the object to be measured from the plurality of first digital data items converted by the plurality of AD converters.

### Advantageous Effects

The measuring device according to the present disclosure can improve the measurement accuracy of an electrical parameter of an object to be measured.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a circuit block diagram illustrating a configuration of a measuring device according to Embodiment 1.

FIG. 2 is a circuit block diagram illustrating a configuration of a measuring device according to Embodiment 2.

FIG. 3 is a circuit block diagram illustrating a configuration of a measuring device according to Embodiment 3.

FIG. 4 is a circuit block diagram illustrating a configuration of a measuring device according to Embodiment 4.

### DESCRIPTION OF EMBODIMENTS

The following describes in detail embodiments of the present disclosure with reference to the drawings. Note that each of the embodiments described below is a specific example of the present disclosure. The numerical values, shapes, materials, structural elements, arrangement and connection of the structural elements, steps, order of the steps, etc., described in the following embodiments are given merely by way of illustration and are not intended to limit the present disclosure. Moreover, each figure is not necessarily a precise depiction. In the figures, structural elements that are essentially the same share like reference signs and overlapping description is omitted or simplified. Moreover, the expressions indicating connection mean electrical connection, and include not only when two circuit elements are connected directly, but also when two circuit elements are indirectly connected to each other with another circuit element inserted between the two circuit elements.

### Embodiment 1

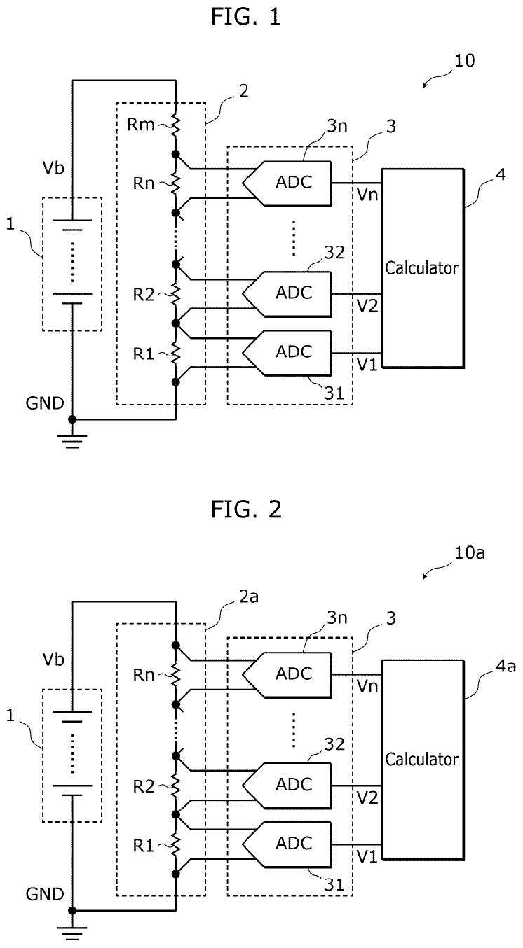

FIG. 1 is a circuit block diagram illustrating a configuration of measuring device 10 according to Embodiment 1. In FIG. 1, measuring device 10 measures the voltage of battery 1, which is an object to be measured, as an electrical parameter of the object to be measured. Battery 1 is a cell stack, which includes cells that are a plurality of batteries, are directly connected to one another. In the embodiment, battery 1 is a lithium-ion battery, but may be any other batteries such as a nickel-metal hydride battery.

Measuring device 10 includes voltage divider resistor component 2, AD converter component 3, and calculator 4. Voltage divider resistor component 2 includes a plurality of voltage divider resistors R1 to Rn and Rm that divide terminal voltage Vb of battery 1 (object to be measured). Here, “n” is a natural number greater than or equal to 2. AD converter component 3 includes a plurality of (here, n) AD converters 31 to 3n that convert the voltages across at least two of the voltage divider resistors (here, voltage divider resistors R1 to Rn) of voltage divider resistor component 2 into first digital data items. Note that, in FIG. 1 and FIGS. 2 to 4 which will be described later, each of the AD converters is denoted as “ADC”.

Calculator 4 calculates the voltage (electrical parameter) of battery 1 (object to be measured) from the first digital data items converted by AD converters 31 to 3n. In Embodiment 1, calculator 4 averages n first digital data items output from AD converter component 3, and calculates voltage Eb of battery 1 from the voltage divider ratio of voltage divider resistor component 2. In other words, calculator 4 calculates an average value of the plurality of first digital data items as a process included in a process of calculating the voltage of battery 1 (object to be measured). Here, voltage Vb is an actual voltage value of battery 1 and voltage Eb is a voltage value calculated by calculator 4 as the voltage of battery 1.

In Embodiment 1, a resistor having a nominal resistance value of “r” is used as each of voltage divider resistors R1 to Rn of voltage divider resistor component 2. Moreover, voltage divider resistor component 2 is configured such that the voltages across voltage divider resistors R1 to Rn fall within the respective input allowable voltage ranges of AD converters 31 to 3n of AD converter component 3. Moreover, in Embodiment 1, a resistor having a nominal resistance value of “rm” is used as voltage divider resistor Rm of voltage divider resistor component 2.

The voltages across voltage divider resistors R1 to Rn of voltage divider resistor component 2 are respectively converted into first digital data items by AD converters 31 to 3n of AD converter component 3. If the respective output values of AD converters 31 to 3n are “V1” to “Vn”, output values V1 to Vn have relationships with terminal voltage Vb of battery 1 as shown in the following equations (1).

$$\begin{matrix}V 1 = ( R 1 / R ) \times Vb + Va 1 \\ V 2 = ( R 2 / R ) \times Vb + Va 2 \\ … \\ Vn = ( Rn / R ) \times Vb + Van\end{matrix} \qquad ( 1 )$$

In equations (1) above, “R1” to “Rn” and “Rm” denote the actual resistance values of voltage divider resistors R1 to Rn and Rm. Moreover, in the above equations (1), the sum of the resistance values of all voltage divider resistors R1 to Rn and Rm is “R (=R1+R2+ . . . +Rn+Rm)”. Moreover, in the above equations (1), the variations in the output values of AD converters 31 to 3n (that is, differences in voltage between the output values and the true value) of AD converter component 3 are respectively referred to as “Vat” to “Van”.

Calculator 4 calculates voltage Eb of battery 1 by multiplying the average value of output values V1 to Vn by a reciprocal of a voltage divider ratio. Here, the voltage divider ratio is expressed by design constant r/(n×r+rm) using the nominal resistance value of each of voltage divider resistors R1 to Rn and Rm. Therefore, the reciprocal of the voltage divider ratio is expressed as (n×r+rm)/r=n+rm/r, which is also a design constant. Voltage Eb of battery 1, which is calculated by calculator 4, is expressed by the following equation (2).

$$Eb = \{ ( V 1 + … + Vn ) / n \} \times ( n + rm / r ) \qquad ( 2 )$$

Here, the average value of V1 to Vn is expressed by the following equation (3).

$$( V 1 + … + Vn ) / n = Vb \times ( R 1 / R + … + Rn / R ) / n + ( Va 1 + … + Van ) / n ) \qquad ( 3 )$$

Accordingly, in the process of calculating voltage Eb of battery 1 by calculator 4, the variations in the voltage divider ratios and the variations in the output values of AD converters 31 to 3n are also averaged. Here, the variations in n average values are 1/√n of the variations in individual values. Therefore, the variations in the voltage divider ratios due to the variations in the resistance values can be reduced to 1/√n, and the variations in the output values of AD converter component 3 can also be reduced to 1/√n.

As described above, in measuring device 10 according to Embodiment 1, terminal voltage Vb of battery 1, which is an object to be measured, is divided by a plurality of voltage divider resistors R1 to Rn and Rm, and among the voltages generated by voltage divider resistors R1 to Rn and Rm, the voltages generated by voltage divider resistor R1 to Rn are converted into a plurality of first digital data items by AD converters 31 to 3n. The average value (V1+ . . . +Vn)/n of the first digital data items is used to calculate voltage Eb of battery 1. Therefore, in measuring device 10 according to Embodiment 1, the accuracy of the resistance values of the voltage divider resistors is less likely to affect the measurement accuracy of the voltage of an object to be measured. Moreover, measuring device 10 in Embodiment 1 does not require a switch circuit as in the method disclosed in PTL 2. Therefore, it is unnecessary to perform complicated timing control for switching the respective terminals of the voltage divider resistors to be sequentially connected to the AD converter using a switch circuit. Furthermore, there is no effect on the measurement accuracy of the voltage due to switching noise resulting from such control. Therefore, measuring device 10 according to Embodiment 1 can improve the measurement accuracy of the voltage (electrical parameter) of battery 1 (object to be measured). Moreover, measuring device 10 according to Embodiment 1 does not require switching control using a switch circuit as described above, and AD converters 31 to 3n perform the measurement almost simultaneously. Therefore, measuring device according to Embodiment 1 is advantageous in that the measurement time can be shortened.

Note that in Embodiment 1, calculator 4 calculates voltage Eb of battery 1 by calculating an average value of output values V1 to Vn and multiplying the average value by the reciprocal of the voltage divider ratio, but the present disclosure is not limited to this example. For example, calculator 4 may calculate voltage Eb of battery 1 by calculating the average value of a plurality of (here, n) voltages obtained by multiplying each of output values V1 to Vn by the reciprocal of the corresponding voltage divider ratio.

Moreover, in Embodiment 1, voltage divider resistors R1 to Rn, which are at least two but not all of the voltage divider resistors of voltage divider resistor component 2, input the voltages across voltage divider resistors R1 to Rn to AD converter component 3, and voltage divider resistors R1 to Rn, which are at least two but not all of the voltage divider resistors, are located on a low electric potential side of battery 1 (object to be measured). With this, in Embodiment 1, the input withstand voltage of AD converter component 3 can be relatively small, and thus the degree of freedom in the design of AD converter component 3 can be improved.

Note that when AD converter component 3 has a sufficient input withstand voltage, the present disclosure is not limited to the above configuration. For example, in Embodiment 1, one or more voltage divider resistors Rm may be provided on the path of the series circuit, or each of one or more voltage divider resistors Rm may be provided at any position on the path of the series circuit.

### Embodiment 2

FIG. 2 is a circuit block diagram illustrating a configuration of measuring device 10a according to Embodiment 2. As illustrated in FIG. 2, measuring device 10a according to Embodiment 2 is different from measuring device 10 according to Embodiment 1 in that measuring device 10a includes voltage divider resistor component 2a instead of voltage divider resistor component 2 (see FIG. 1) and voltage divider resistor component 2a does not include voltage divider resistor Rm. Moreover, the function of calculator 4a of measuring device 10a according to Embodiment 2 is different from the function of calculator 4 of measuring device 10 according to Embodiment 1. Note that description of points in common to measuring device 10 according to Embodiment 1 will be basically omitted.

In Embodiment 2, a resistor having a nominal resistance value of “r” is used as each of voltage divider resistors R1 to Rn of voltage divider resistor component 2a, as with Embodiment 1. Moreover, voltage divider resistor component 2a is configured such that the voltages across voltage divider resistors R1 to Rn fall within the input allowable voltage range of AD converters 31 to 3n of AD converter component 3. Moreover, in Embodiment 2, the voltages across voltage divider resistors R1 to Rn of voltage divider resistor component 2a are respectively converted into first digital data items by AD converters 31 to 3n of AD converter component 3, as with Embodiment 1. As with Embodiment 1, if the respective output values of AD converters 31 to 3n are “V1” to “Vn”, output values V1 to Vn have relationships with terminal voltage Vb of battery 1 as shown in the following equations (4).

$$\begin{matrix}V 1 = ( R 1 / Ra ) \times Vb + Va 1 \\ V 2 = ( R 2 / Ra ) \times Vb + Va 2 \\ … \\ Vn = ( Rn / Ra ) \times Vb + Van\end{matrix} \qquad ( 4 )$$

In the above equations (4), the sum of the resistance values of all voltage divider resistors R1 to Rn is “Ra (=R1+R2+ . . . +Rn)”.

Calculator 4a calculates voltage Eb of battery 1 by calculating the sum of the above output values V1 to Vn. Voltage Eb of battery 1 calculated by calculator 4a is expressed by the following equation

$$Eb = V 1 + V 2 + … + Vn = Vb + Va 1 + Va 2 + … + Van \qquad ( 5 )$$

Accordingly, in the process of calculating voltage Eb of battery 1 by calculator 4a, variations in the voltage divider ratios, i.e., variations in the resistance values are canceled, and the sum of the variations in the output values of AD converters 31 to 3n is a difference voltage between the calculated voltage Eb and the actual voltage Vb of battery 1.

As described above, in measuring device 10a according to Embodiment 2, all voltage divider resistors R1 to Rn of voltage divider resistor component 2a input voltages across voltage divider resistors R1 to Rn to AD converter component 3, and calculator 4a calculates the voltage of battery 1 (object to be measured) by summing first digital data items (output values V1 to Vn). Therefore, since there are no variations in the voltage divider ratios due to variations in voltage divider resistors R1 to Rn in measuring device 10a according to Embodiment 2, the accuracy of the resistance values of the voltage divider resistors is less likely to affect the measurement accuracy of the voltage of an object to be measured. Moreover, as with measuring device 10 according to Embodiment 1, measuring device 10a according to Embodiment 2 does not require a switch circuit. Therefore, measuring device 10a according to Embodiment 2 can improve the measurement accuracy of the voltage (electrical parameter) of battery 1 (object to be measured), as with measuring device 10 according to Embodiment 1. Moreover, measuring device 10a according to Embodiment 2 is advantageous in that the measurement time can be shortened, as with measuring device 10 according to Embodiment 1.

Note that, for example, if the voltage of the object to be measured is relatively high and there would be too many AD converters when an AD converter is provided for each voltage divider resistor, measurement device 10 according to Embodiment 1 may be adopted.

### Embodiment 3

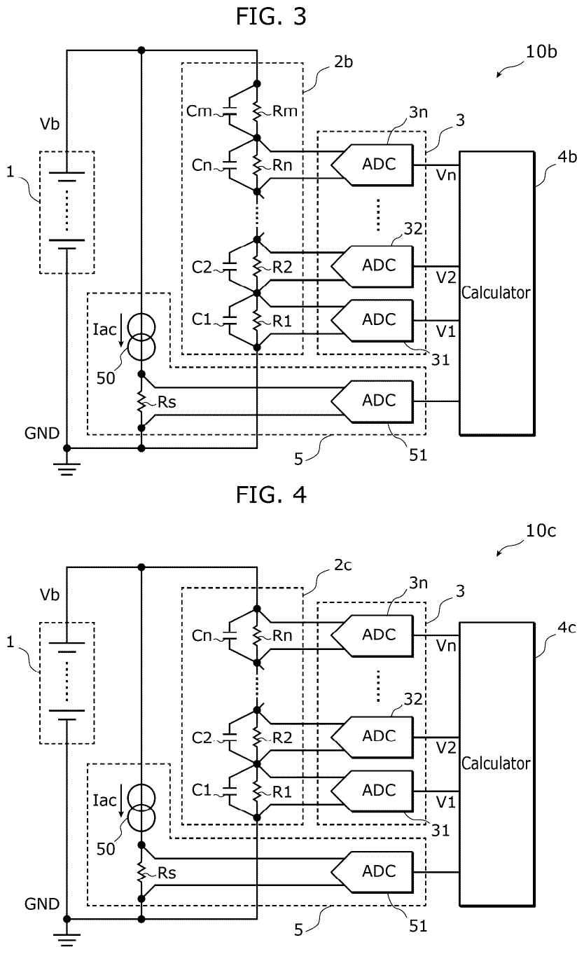

FIG. 3 is a circuit block diagram illustrating a configuration of measuring device 10b according to Embodiment 3. In FIG. 3, measuring device 10b measures the AC impedance of battery 1, which is an object to be measured, as an electrical parameter of the object to be measured.

As illustrated in FIG. 3, measuring device 10b according to Embodiment 3 includes voltage divider resistor component 2b instead of voltage divider resistor component 2 (see FIG. 1), and is different from measuring device 10 according to Embodiment 1 in that voltage divider resistor component 2b includes a plurality of (here, n+1) capacitors C1 to Cn and Cm. In addition, measuring device 10b according to Embodiment 3 is different from measuring device 10 according to Embodiment 1 in that measuring device 10b further includes current detection component 5 that detects current Iac flowing through battery 1 (object to be measured) and outputs a current detection signal. Moreover, the function of calculator 4b of measuring device 10b according to Embodiment 3 is different from the function of calculator 4 of measuring device 10 according to Embodiment 1. Specifically, calculator 4b is different from calculator 4 of measuring device 10 according to Embodiment 1 in that calculator 4b includes a function of calculating the AC impedance of battery 1 (object to be measured) as an electrical parameter. Note that description of points in common to measuring device 10 according to Embodiment 1 will be basically omitted.

Voltage divider resistor component 2b includes a plurality of voltage divider resistors R1 to Rn and Rm, and a plurality of capacitors C1 to Cn and Cm each connected in parallel to a corresponding one of voltage divider resistors R1 to Rn and Rm. Capacitors C1 to Cn and Cm and corresponding voltage divider resistors R1 to Rn and Rm form high pass filters.

Here, as a result of diligent studies, the inventors found that voltage divider resistors R1 to Rn and Rm and the parasitic capacitance of the input wirings of AD converters 31 to 3n form low-pass filters and change the respective input voltage values of AD converters 31 to 3n. This effect of the low-pass filters was more pronounced as the resistance values of the voltage divider resistors were higher, and hindered the preservation of the frequency response of the first digital data items output by the respective AD converters 31 to 3n.

In view of this, in measuring device 10b according to Embodiment 3, capacitors C1 to Cn and Cm are each connected in parallel to a corresponding one of voltage divider resistors R1 to Rn and Rm. As a result, measuring device 10b according to Embodiment 3 makes it easier to reduce the effects of the low-pass filters described above, and maintain the frequency response of the first digital data items output by AD converters 31 to 3n.

Current detection component 5 includes current source circuit 50, detection resistor Rs as a current detector, and AD converter 51. Current source circuit 50 includes a function of applying current Iac including an AC component to battery 1 (object to be measured). Moreover, current source circuit 50 includes a function of changing the frequency of the AC component of current Iac over time, i.e., sweeping the frequency. In Embodiment 3, current source circuit 50 includes a function of changing the frequency of the AC component of current Iac in stages (discretely) over time.

Detection resistor Rs is connected in series to current source circuit 50. Detection resistor Rs detects current Iac including the AC component by converting current Iac applied by current source circuit 50 into a voltage. AD converter 51 converts the voltage across detection resistor Rs, that is, the output of the current detector, into a second digital data item. With this, current detection component 5 outputs the second digital data item as a current detection signal.

Here, analog data is input to n AD converters 31 to 3n of AD converter component 3 and AD converter 51 of current detection component 5 at the same sampling timing. Note that the first digital data items output from AD converters 31 to 3n are denoted as “voltage digital data items”. Moreover, the second digital data item output from AD converter 51 is denoted as a “current digital data item”.

Calculator 4b calculates, as the electrical parameter, an AC impedance of battery 1 (object to be measured) based on the plurality of first digital data items (voltage digital data items) and the second digital data item (current digital data item). Here, calculator 4b includes a function of calculating the AC impedance based on (i) the average value of the plurality of first digital data items and (ii) the second digital data item.

Specifically, current Iac including the AC component from current source circuit 50 is input, as the second digital data item for each sampling cycle of AD converter 51, to calculator 4b for at least one cycle of current Iac. Moreover, the voltage of battery 1 that changes with current Iac is input, as the first digital data items for each sampling cycle of AD converters 31 to 3n, to calculator 4b also for at least one cycle of current Iac.

Calculator 4b averages the first digital data items. Then, calculator 4b performs calculation processing such as fast Fourier transform on the data obtained by averaging the first digital data items and the second digital data item. With this, the AC impedance of battery 1, which includes a real part and an imaginary part for each frequency of current Iac including the AC component from current source circuit 50, is calculated. In addition, calculator 4b can obtain the frequency response of the internal impedance of battery 1 by storing, in memory, the AC impedance data calculated for each frequency swept in stages by current source circuit 50. The frequency response of the internal impedance of battery 1 is used, for example, for diagnosis of degradation of battery 1.

The AC impedance of battery 1 calculated by calculator 4b is expressed by the following equation (6). In the following equation (6), “Z” indicates the AC impedance of battery 1. Moreover, in the following equation (6), “Iac” indicates a current value of current Iac including the AC component from current source circuit 50.

$$[ Math . 1 ]$$

$$Z = \frac{Eb}{Iac} = \frac{Vb \times \frac{( \frac{R 1}{R} + \frac{R 2}{R} + … + \frac{Rn}{R} )}{n} + \frac{Va 1 + Va 2 + … + Van}{n}}{Iac} \times ( n + \frac{rm}{r} ) \qquad ( 6 )$$

Here, when the internal impedance of battery 1, which is an object to be measured, is relatively low, the AC component is smaller than the direct-current (DC) component in the voltage of battery 1. In such cases, measurement of the voltage of battery 1 is required to be synchronized with measurement of the current flowing through battery 1 and is required to be highly accurate. In order to achieve high measurement accuracy, it is necessary to reduce variations in the resistance values of the voltage divider resistors.

As a method of reducing variations in the resistance values of the voltage divider resistors may be, for example, measuring the voltage and the current of battery 1 a plurality of times, and then averaging the measurement results. However, when the current of battery 1 is measured a plurality of times, this lead to problems such as increase in the measurement time, decrease in the state of charge (SOC) of battery 1, and change in the temperature of battery 1, and thus the AC impedance of battery 1 could not be accurately measured.

In contrast, in measuring device 10b according to Embodiment 3, the configurations of voltage divider resistor component 2b and AD converter component 3 are respectively the same as the configurations of voltage divider resistor component 2 and AD converter component 3 of measuring device 10 according to Embodiment 1. Therefore, measuring device 10b according to Embodiment 3 can improve the measurement accuracy of the voltage of battery 1 as with measuring device 10 according to Embodiment 1 even when measurement is performed once, because variations in the voltage divider ratios and variations in the output values of AD converters 31 to 3n are both averaged and reduced, and are less likely to affect the measurement accuracy of the voltage of battery 1. Accordingly, measuring device 10b according to Embodiment 3 can measure the voltage and the current of battery 1 simultaneously, and it is sufficient to perform the measurement once. Therefore, the above-described problems do not occur in measuring device 10b according to Embodiment 3. Thus, measuring device 10b according to Embodiment 3 can improve the measurement accuracy of the AC impedance of battery 1 (object to be measured), and also reduce the measurement time.

Note that in Embodiment 3, calculator 4b calculates the AC impedance of battery 1 from the average value of the plurality of (here, n) first digital data items and the second digital data item, but the present disclosure is not limited to this. For example, calculator 4b may calculate the AC impedance of battery 1 by calculating a plurality of AC impedances from combinations of each of the first digital data items with the second digital data item, and calculating the average value of the plurality of AC impedances calculated.

Moreover, in Embodiment 3, detection resistor Rs of current detection component 5 may be replaced with a circuit in which a plurality of detection resistors are connected in parallel. In this case, variations in the resistance values of the detection resistors can be reduced, and thus the accuracy of the resistance values of the detection resistors is less likely to affect the measurement accuracy of the current of battery 1. Therefore, the measurement accuracy of the current of battery 1 can be improved.

As described above, measuring device 10b according to Embodiment 3 is useful as a device that measures the AC impedance of battery 1, for example, when battery 1 is a relatively high voltage battery such as a cell stack, or when battery 1 is a battery pack whose voltage per cell cannot be measured.

### Embodiment 4

FIG. 4 is a circuit block diagram illustrating a configuration of measuring device 10c according to Embodiment 4. As illustrated in FIG. 4, measuring device 10c according to Embodiment 4 is different from measuring device 10b according to Embodiment 3 in that measuring device 10c includes voltage divider resistor component 2c instead of voltage divider resistor component 2b (see FIG. 3), and voltage divider resistor component 2c does not include voltage divider resistor Rm and capacitor Cm. Moreover, the function of calculator 4c of measuring device 10c according to Embodiment 4 is different from the function of calculator 4b of measuring device 10b according to Embodiment 3. Note that description of points in common to measuring device 10b according to Embodiment 3 will be basically omitted.

In Embodiment 4, a resistor having a nominal resistance value of “r” is used as each of voltage divider resistors R1 to Rn of voltage divider resistor component 2c, as with Embodiment 3. Moreover, voltage divider resistor component 2c is configured such that the voltages across voltage divider resistors R1 to Rn fall within the input allowable voltage range of AD converters 31 to 3n of AD converter component 3. Moreover, in Embodiment 4, the voltages across voltage divider resistors R1 to Rn of voltage divider resistor component 2c are converted into first digital data items by AD converters 31 to 3n of AD converter component 3, as with Embodiment 3.

Moreover, in Embodiment 4, a plurality of capacitors C1 to Cn of voltage divider resistor component 2c are each connected in parallel to a corresponding one of voltage divider resistors R1 to Rn, as with Embodiment 3. Therefore, in Embodiment 4, capacitors C1 to Cn form high pass filters with corresponding voltage divider resistors R1 to Rn, as with Embodiment 3. Therefore, this makes it easier to maintain the frequency response of the first digital data items output by AD converters 31 to 3n.

Calculator 4c performs calculation processing such as fast Fourier transform on the data obtained by summing the plurality of first digital data items (voltage digital data items) and the second digital data item (current digital data item). With this, the AC impedance of battery 1, which includes a real part and an imaginary part for each frequency of current Iac including the AC component from current source circuit 50, is calculated. Then, calculator 4c can obtain the frequency response of the internal impedance of battery 1 by storing, in memory, the data of the AC impedance calculated for each frequency swept in stages by current source circuit 50.

The AC impedance of battery 1 calculated by calculator 4c is expressed by the following equation (7).

$$[ Math . 2 ]$$

$$Z = \frac{Eb}{Iac} = \frac{Vb \times ( \frac{R 1}{Ra} + \frac{R 2}{Ra} + … + \frac{Rn}{Ra} ) + Va 1 + Va 2 + … + Van}{Iac} \qquad ( 7 )$$

As described above, in measuring device 10c according to Embodiment 4, all voltage divider resistors R1 to Rn of voltage divider resistor component 2c input the voltages across voltage divider resistors R1 to Rn to AD converter component 3, and calculator 4c calculates the AC impedance of battery 1 (object to be measured) after summing the plurality of first digital data items (output values V1 to Vn). Therefore, since there are no variations in voltage divider ratios due to variations in voltage divider resistors R1 to Rn in measuring device 10c according to Embodiment 4, the accuracy of the resistance values of the voltage divider resistors is less likely to affect the accuracy of the voltage measurement of battery 1. Therefore, measuring device 10c according to Embodiment 4 can improve the measurement accuracy of the AC impedance of battery 1 (object to be measured), and also reduce the measurement time, as with measuring device 10b according to Embodiment 3.

Note that in Embodiment 4, calculator 4c calculates the AC impedance of battery 1 from the sum of the plurality of (here, n) first digital data items and the second digital data item, but the present disclosure is not limited to this. For example, calculator 4c may calculate the AC impedance of battery 1 by calculating a plurality of AC impedances from combinations of each of the first digital data items with the second digital data item, and summing the plurality of AC impedances calculated.

As described above, measuring device 10c according to Embodiment 3 is useful as a device that measures the AC impedance of battery 1, for example, when battery 1 is a battery pack that includes a cell stack and whose voltage per cell cannot be measured, but AD converters can be connected to all voltage divider resistors provided across the terminals of battery 1.

As described above, measuring devices 10, 10a, 10b, and 10c according to Embodiments 1 to 4 respectively include voltage divider resistor components 2, 2a, 2b, and 2c; AD converter component 3; and calculators 4, 4a, 4b, and 4c. Voltage divider resistor components 2, 2a, 2b, and 2c each include a plurality of voltage divider resistors R1 to Rn and Rm (or R1 to Rn) that divide the voltage of battery 1 (object to be measured). AD converter component 3 includes a plurality of AD converters 31 to 3n that convert voltages of at least two of the plurality of voltage divider resistors of voltage divider resistor component 2 into a plurality of first digital data items, the voltages each being a voltage across a voltage divider resistor among the at least two of the plurality of voltage divider resistors. Calculators 4, 4a, 4b, and 4c calculate an electrical parameter of battery 1 (object to be measured) from the plurality of first digital data items converted by the plurality of AD converters 31 to 3n.

With this, the accuracy of the resistance values of the voltage divider resistors is less likely to affect the accuracy of the electrical parameter of battery 1 (object to be measured). Moreover, with this, a switch circuit is not required, and therefore, complicated timing control for switching the terminals of the respective voltage divider resistors to sequentially connect to the AD converters using a switch circuit is unnecessary. Furthermore, there is no effect on the measurement accuracy of the voltage due to switching noise resulting from such control. Therefore, the measurement accuracy of the electrical parameter of battery 1 (object to be measured) can be improved.

Moreover, in measuring devices 10 and 10a according to Embodiments 1 and 2, each of calculators 4 and 4a calculates, as the electrical parameter, the voltage of battery 1 (object to be measured).

With this, the measurement accuracy of the voltage of battery 1 (object to be measured) can be improved.

Moreover, in measuring devices 10 and 10a according to Embodiments 1 and 2, each of calculators 4 and 4a calculates an average value of the plurality of first digital data items as a process included in a process of calculating the voltage of battery 1 (object to be measured.

With this, variations in the output values of AD converters 31 to 3n can be reduced.

Moreover, in measuring device 10 according to Embodiment 1, the at least two voltage divider resistors R1 to Rn of the plurality of voltage divider resistors are not all of the plurality of voltage divider resistors of voltage divider resistor component 2, each of at least two voltage divider resistors R1 to Rn of the plurality of voltage divider resistors of voltage divider resistor component 2 inputs a voltage across the voltage divider resistor to AD converter component 3. The at least two voltage divider resistors R1 to Rn of the plurality of voltage divider resistors are located on a low electric potential side of battery 1 (object to be measured).

With this, the input withstand voltage of AD converter component 3 can be relatively small, and thus the degree of freedom in the design of AD converter component 3 can be improved.

Moreover, measuring device 10a according to Embodiment 2, the at least two voltage divider resistors R1 to Rn of the plurality of voltage divider resistors are all of the plurality of voltage divider resistors of voltage divider resistor component 2, each of the at least two voltage divider resistors R1 to Rn of the plurality of voltage divider resistors of voltage divider resistor component 2 inputs a voltage across the voltage divider resistor to AD converter component 3. Calculator 4a calculates the voltage of battery 1 (object to be measured) by summing the plurality of first digital data items.

With this, because there are no variations in the voltage divider ratios due to variations in the voltage divider resistors, the accuracy of the resistance values of the voltage divider resistors is less likely to affect the accuracy of the electrical parameter of battery 1 (object to be measured).

Moreover, measuring devices 10b and 10c according to Embodiments 3 and 4 further include current detection component 5 that detects current Iac flowing through battery 1 (object to be measured) and outputs a current detection signal. Each of calculators 4b and 4c calculates, as the electrical parameter, an alternating-current (AC) impedance of battery 1 (object to be measured), based on the plurality of first digital data items and the current detection signal.

With this, the voltage and the current of battery 1 (object to be measured) can be measured simultaneously, and it is sufficient to perform the measurement once. Therefore, with this, the measurement accuracy of the AC impedance of battery 1 (object to be measured) can be improved and also the measurement time can be reduced.

Moreover, in each of measuring devices 10b and 10c according to Embodiments 3 and 4, current detection component 5 includes: current source circuit 50 that applies current Iac including an AC component to battery 1 (object to be measured); detection resistor Rs (current detector) that detects current Iac including the AC component; and AD converter 51 that converts output of detection resistor Rs (current detector) into a second digital data item. Moreover, current detection component 5 outputs the second digital data item as the current detection signal.

With this, the measurement accuracy of current Iac including the AC component flowing through battery 1 (object to be measured) can be improved.

Moreover, in measuring device 10b according to Embodiment 3, calculator 4b includes a function of calculating the AC impedance of battery 1 (object to be measured), based on (i) an average value of the plurality of first digital data items and (ii) the second digital data item, or calculating the AC impedance of battery 1 (object to be measured) by calculating an average value of a plurality of AC impedances calculated based on the plurality of first digital data items and the second digital data item.

With this, variations in the output values of AD converters 31 to 3n can be reduced.

Moreover, in measuring device 10c according to Embodiment 4, the at least two voltage divider resistors R1 to Rn of the plurality of voltage divider resistors are all of the plurality of voltage divider resistors of voltage divider resistor component 2, each of the at least two voltage divider resistors R1 to Rn of the plurality of voltage divider resistors of voltage divider resistor component 2 inputs a voltage across the voltage divider resistor to AD converter component 3. Calculator 4c includes a function of calculating the AC impedance of battery 1 (object to be measured), based on (i) a sum of the plurality of first digital data items and (ii) the second digital data item, or calculating the AC impedance of battery 1 (object to be measured) by summing a plurality of AC impedances calculated based on the plurality of first digital data items and the second digital data item.

With this, because there are no variations in the voltage divider ratios due to variations in the voltage divider resistors, the accuracy of the resistance values of the voltage divider resistors is less likely to affect the accuracy of the AC impedance of battery 1 (object to be measured).

Moreover, in each of measuring devices 10b and 10c according to Embodiments 3 and 4, current source circuit 50 includes a function of changing a frequency of the AC component over time.

With this, the frequency response of an internal impedance of battery 1 (object to be measured) can be obtained.

Moreover, in each of measuring devices 10b and 10c according to Embodiments 3 and 4, current source circuit 50 includes a function of changing the frequency of the AC component in stages over time.

With this, the frequency response of the internal impedance of battery 1 (object to be measured) can be obtained.

Moreover, each of measuring devices 10b and 10c according to Embodiments 3 and 4 further includes a plurality of capacitors C1 to Cn and Cm (or C1 to Cn) each connected in parallel to a corresponding one of the plurality of voltage divider resistors R1 to Rn and Rm (or R1 to Rn).

With this, the effects of low-pass filters formed by the voltage divider resistors and the parasitic capacitance of the input wirings of AD converters 31 to 3n can be reduced. Therefore, it is easier to maintain the frequency response of the first digital data items output by AD converters 31 to 3n.

The measuring device according to the present disclosure has been described above based on Embodiments 1 to 4, but the present disclosure should not be limited to these embodiments. Various modifications of the embodiments as well as embodiments resulting from combinations of one or more structural elements of the different embodiments that may be conceived by those skilled in the art may be included within the scope of the one or more aspects as long as these do not depart from the teachings of the present disclosure.

For example, in Embodiments 1 to 4 described above, the object to be measured is battery 1, which is a cell stack, but the object to be measured may be a single battery. Also in this case, the measurement can be performed in the same manner as in Embodiments 1 to 4.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The measuring device according to the present disclosure can be used as a measuring device that measures an electrical parameter (voltage or AC impedance) of an object to be measured, for example, a battery such as a lithium-ion battery.

1. A measuring device comprising:
a voltage divider resistor component including a plurality of voltage divider resistors that divide a voltage of an object to be measured;
an analog-to-digital (AD) converter component including a plurality of AD converters that convert voltages of at least two of the plurality of voltage divider resistors of the voltage divider resistor component into a plurality of first digital data items, the voltages each being a voltage across a voltage divider resistor among the at least two of the plurality of voltage divider resistors; and
a calculator that calculates an electrical parameter of the object to be measured from the plurality of first digital data items converted by the plurality of AD converters.

2. The measuring device according to claim 1, wherein
the calculator calculates, as the electrical parameter, the voltage of the object to be measured.

3. The measuring device according to claim 1, wherein
the calculator calculates an average value of the plurality of first digital data items as a process included in a process of calculating the voltage of the object to be measured.

4. The measuring device according to claim 1, wherein
the at least two of the plurality of voltage divider resistors are not all of the plurality of voltage divider resistors of the voltage divider resistor component,
each of the at least two of the plurality of voltage divider resistors of the voltage divider resistor component inputs a voltage across the voltage divider resistor to the AD converter component, and
the at least two of the plurality of voltage divider resistors are located on a low electric potential side of the object to be measured.

5. The measuring device according to claim 1, wherein
the at least two of the plurality of voltage divider resistors are all of the plurality of voltage divider resistors of the voltage divider resistor component,
each of the at least two of the plurality of voltage divider resistors of the voltage divider resistor component inputs a voltage across the voltage divider resistor to the AD converter component, and
the calculator calculates the voltage of the object to be measured by summing the plurality of first digital data items.

6. The measuring device according to claim 1, further comprising:
a current detection component that detects a current flowing through the object to be measured and outputs a current detection signal, wherein
the calculator calculates, as the electrical parameter, an alternating-current (AC) impedance of the object to be measured, based on the plurality of first digital data items and the current detection signal.

7. The measuring device according to claim 6, wherein
the current detection component includes:
a current source circuit that applies a current including an AC component to the object to be measured;
a current detector that detects the current including the AC component; and
an AD converter that converts output of the current detector into a second digital data item, and
the current detection component outputs the second digital data item as the current detection signal.

8. The measuring device according to claim 7, wherein
the calculator includes a function of calculating the AC impedance of the object to be measured, based on (i) an average value of the plurality of first digital data items and (ii) the second digital data item, or calculating the AC impedance of the object to be measured by calculating an average value of a plurality of AC impedances calculated based on the plurality of first digital data items and the second digital data item.

9. The measuring device according to claim 7, wherein
the at least two of the plurality of voltage divider resistors are all of the plurality of voltage divider resistors of the voltage divider resistor component,
each of the at least two of the plurality of voltage divider resistors of the voltage divider resistor component inputs a voltage across the voltage divider resistor to the AD converter component, and
the calculator includes a function of calculating the AC impedance of the object to be measured, based on (i) a sum of the plurality of first digital data items and (ii) the second digital data item, or calculating the AC impedance of the object to be measured by summing a plurality of AC impedances calculated based on the plurality of first digital data items and the second digital data item.

10. The measuring device according to claim 7, wherein
the current source circuit includes a function of changing a frequency of the AC component over time.

11. The measuring device according to claim 10, wherein
the current source circuit includes a function of changing the frequency of the AC component in stages over time.

12. The measuring device according to claim 6, further comprising:
a plurality of capacitors each connected in parallel to a corresponding one of the plurality of voltage divider resistors.
